(19) United States
(12) Patent Application Publication
(10) Pub. No.: US 2026/0262285 A1
(43) Pub. Date: Sep. 3, 2026

(54) SEMICONDUCTOR DEVICE WITH CMOS LOGIC CIRCUITS THAT OPERATE ON PLURAL POWER VOLTAGES

(71) Applicant: MICRON TECHNOLOGY, INC., BOISE, ID (US)

(72) Inventors: Kenichi Watanabe, Sagamihara-shi (JP); Moeha Shibuya, Sagamihara-shi (JP); Misato Gemba, Sagamihara-shi (JP)

(73) Assignee: MICRON TECHNOLOGY, INC., Boise, ID (US)

(21) Appl. No.: 19/543,593

(22) Filed: Feb. 18, 2026

Related U.S. Application Data
(60) Provisional application No. 63/765,205, filed on Feb. 28, 2025.

(51) Int. Cl. H10D 84/85; H03K 19/0948; H10D 62/10; G11C 11/4078; G11C 11/408

(52) U.S. Cl. CPC H10D 84/859; H03K 19/0948; H10D 62/126; G11C 11/4078; G11C 11/408

(57) ABSTRACT

An example functional circuit includes: a first CMOS logic circuit supplied with a first voltage, the first CMOS logic circuit including a first PMOS transistor and a first NMOS transistor; a second CMOS logic circuit supplied with a second voltage different from the first voltage, the second CMOS logic circuit including a second PMOS transistor and a second NMOS transistor; and a third CMOS logic circuit supplied with the first voltage, the third CMOS logic circuit including a third PMOS transistor and a third NMOS transistor. The first, second and third PMOS transistors are independently provided in first, second and third nwells, respectively. The first NMOS transistor is provided in a first pwell. The second and third NMOS transistors are provided in a second pwell.

### CROSS-REFERENCE TO RELATED APPLICATIONS

This application claims the filing benefit of U.S. Provisional Application No. 63/765,205, filed February 28, 2025. This application is incorporated by reference herein in its entirety and for all purposes.

### BACKGROUND

In a semiconductor device such as a DRAM, there is a case where a plurality of power sources each having a mutually different level are used. In this case, a transistor to which a certain power source is supplied and another transistor to which a different power source is supplied are respectively formed in mutually different wells.

### BRIEF DESCRIPTION OF THE DRAWINGS

FIG. 1 is a block diagram showing a configuration of a semiconductor memory device according to an embodiment of the present disclosure;

FIG. 2 is a block diagram showing some of circuits included in a fuse latch circuit;

FIG. 3 is a circuit diagram of some of circuits included in a DICE latch circuit;

FIG. 4 is a circuit diagram of some of circuits included in a selector circuit;

FIG. 5 is a circuit diagram of some of circuits included in a control circuit;

FIG. 6 is a schematic plan view for explaining a layout of the fuse latch circuit;

FIG. 7A is a schematic plan view for explaining a layout of transistors included in circuit blocks;

FIG. 7B is a schematic cross section along the line A-A shown in FIG. 7A;

FIG. 8A is a schematic plan view for explaining a layout of transistors included in circuit blocks according to a comparative example;

FIG. 8B is a schematic cross section along the line B-B shown in FIG. 8A;

FIG. 9A is a schematic plan view of the layout according to the comparative example shown in FIGS. 8A and 8B; and

FIG. 9B is a schematic plan view of the layout shown in FIGS. 7A and 7B.

### DETAILED DESCRIPTION

Various embodiments of the present disclosure will be explained below in detail with reference to the accompanying drawings. The following detailed description refers to the accompanying drawings that show, by way of illustration, specific aspects, and various embodiments of the present disclosure. The detailed description provides sufficient detail to enable those skilled in the art to practice these embodiments of the present disclosure. Other embodiments may be utilized, and structural, logical, and electrical changes may be made without departing from the scope of the present disclosure. The various embodiments disclosed herein are not necessarily mutually exclusive, as some disclosed embodiments can be combined with one or more other disclosed embodiments to form new embodiments.

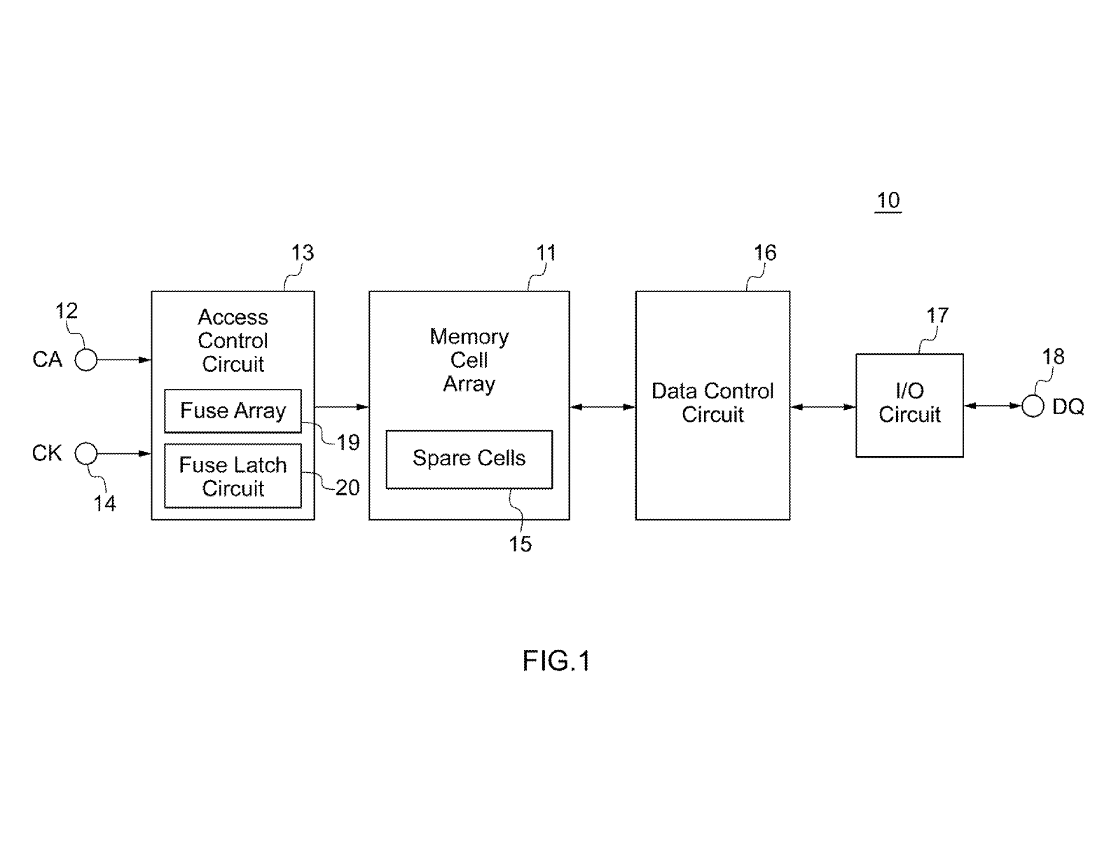

FIG. 1 is a block diagram showing a configuration of a semiconductor memory device 10 according to an embodiment of the present disclosure. The semiconductor memory device 10 shown in FIG. 1 includes a memory cell array 11. When the memory cell array 11 is accessed, a command address signal CA is input to a command address terminal 12 from outside. The command address signal CA is supplied to an access control circuit 13. The access control circuit 13 synchronizes with an external clock signal CK input to a clock terminal 14 to perform decoding of the command address signal CA, latency counting, and the like.

The memory cell array 11 includes not only regular memory cells but also spare memory cells 15 used for replacing defective regular memory cells. The address of a defective regular memory cell is held in a fuse array 19 in a nonvolatile manner. The address held in the fuse array 19 is transferred to a fuse latch circuit 20 in an initializing operation performed after resetting. The fuse latch circuit 20 holds the address of the defective regular memory cell in a volatile manner. Subsequently, when an address included in the command address signal CA matches the address held in the fuse latch circuit 20, the relevant spare memory cell 15 is accessed.

When a command included in the command address signal CA indicates a read operation, the access control circuit 13 makes read access to a memory cell (or a spare memory cell) included in the memory cell array 11 based on the address included in the command address signal CA. Read data DQ read from the accessed memory cell is output to outside from a data I/O terminal 18 via a data control circuit 16 and a data I/O circuit 17. When the command included in the command address signal CA indicates a write operation, write data DQ input to the data I/O terminal 18 is transferred to the memory cell array 11 via the data I/O circuit 17 and the data control circuit 16. The write data DQ transferred to the memory cell array 11 is written in a memory cell (or a spare memory cell) included in the memory cell array 11 based on the address included in the command address signal CA.

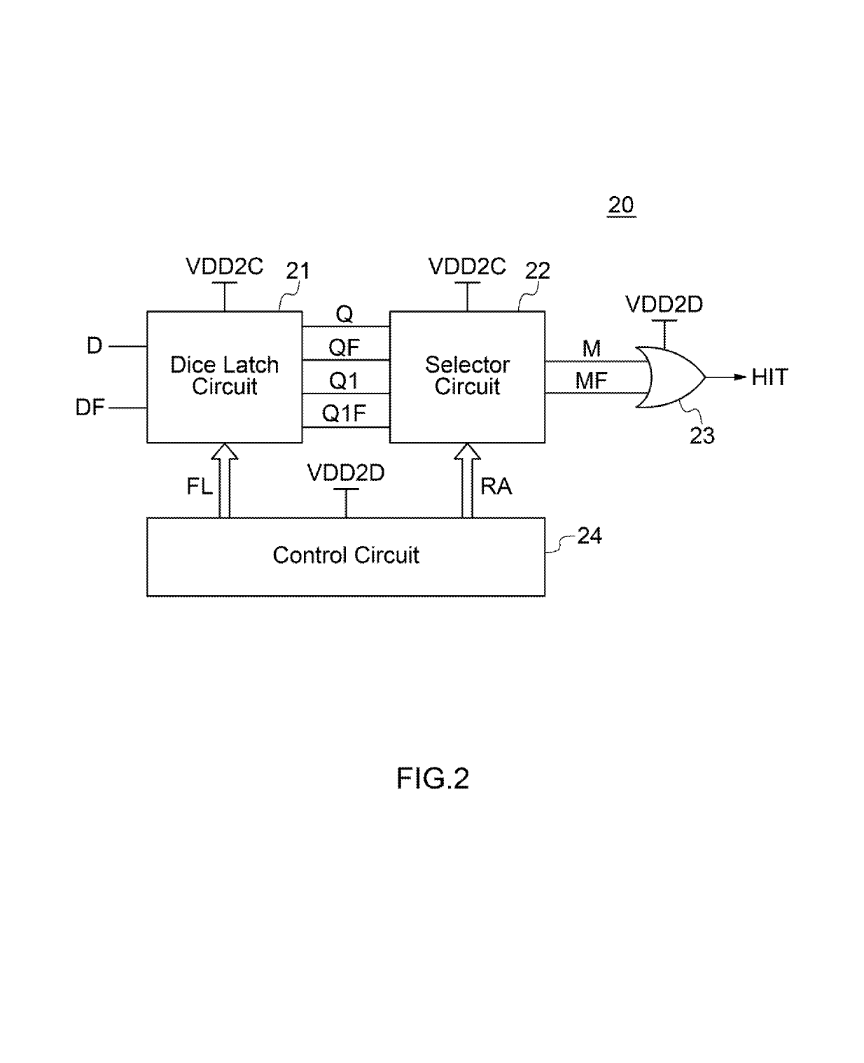

FIG. 2 is a block diagram showing some of the circuits included in the fuse latch circuit 20. As shown in FIG. 2, the fuse latch circuit 20 includes a DICE latch circuit 21, a selector circuit 22, an output circuit 23, and a control circuit 24.

Fuse data D and fuse data DF as an inversion signal of the fuse data D are supplied from the fuse array 19 to the DICE latch circuit 21. When a fuse load signal FL is activated, the DICE latch circuit 21 latches a logic level indicated by the fuse data D and the fuse data DF. The DICE latch circuit 21 outputs latch data Q and latch data QF as an inversion signal of the latch data Q as well as latch data Q1 and latch data Q1F as an inversion signal of the latch data Q1 based on the latched logic level. The selector circuit 22 compares the latch data Q, QF, Q1, and Q1F with an address RA and generates a determination signal M and a determination signal MF as an inversion signal of the determination signal M based on the comparison result. The determination signals M and MF are supplied to an output circuit 23 formed of an OR gate circuit. The output circuit 23 generates a hit signal HIT based on the determination signals M and MF. Activation of the hit signal HIT indicates that an address input from outside matches the address of a defective regular memory cell.

The fuse load signal FL and the address RA are supplied from the control circuit 24. As an operation power source, a power potential VDD2D is supplied to the control circuit 24 and the output circuit 23. For example, the level of the power potential VDD2D is 0.9V. Meanwhile, as an operation power source, a power potential VDD2C is supplied to the DICE latch circuit 21 and the selector circuit 22. For example, the level of the power potential VDD2C is 1.0V. In this manner, by using the power potential VDD2C being a higher potential as the operation power source of the DICE latch circuit 21 and the selector circuit 22, operation reliability of the DICE latch circuit 21 and the selector circuit 22 is improved.

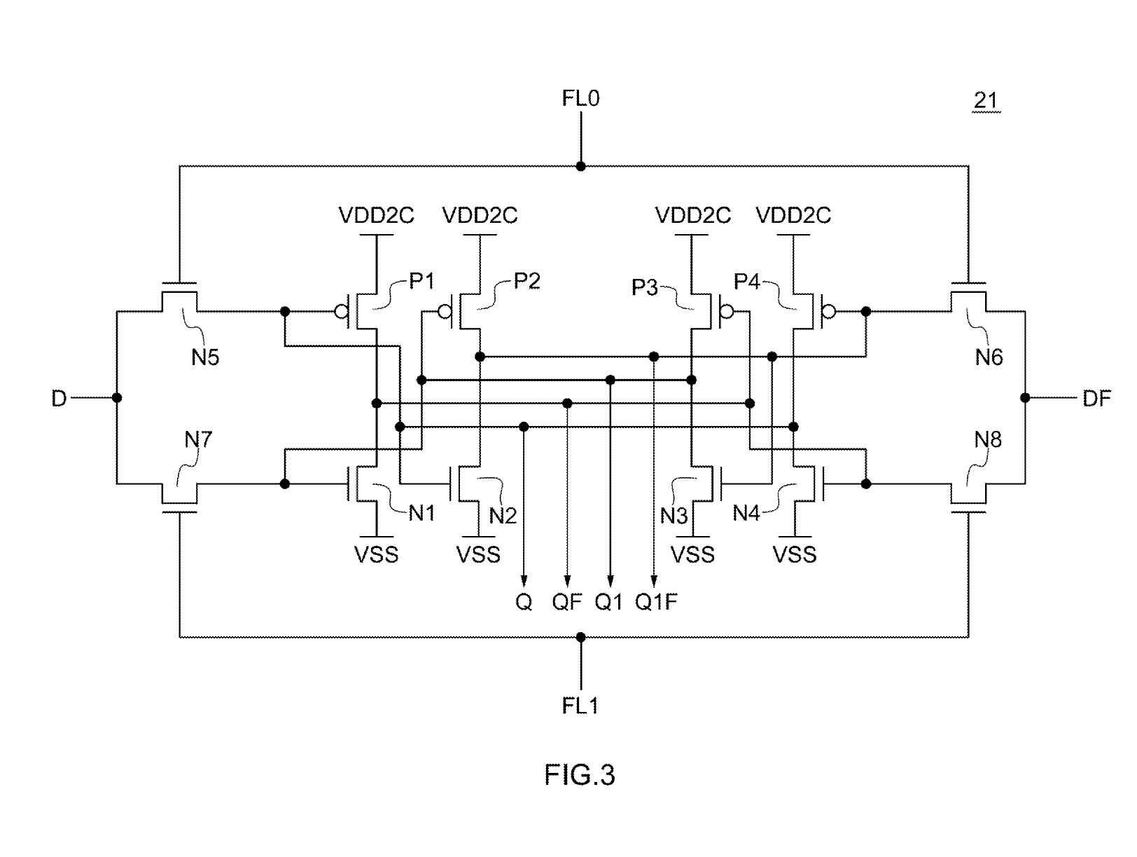

FIG. 3 is a circuit diagram of some of the circuits included in the DICE latch circuit 21. As shown in FIG. 3, the DICE latch circuit 21 includes a series circuit of a P-channel MOS transistor P1 and an N-channel MOS transistor N1, a series circuit of a P-channel MOS transistor P2 and an N-channel MOS transistor N2, a series circuit of a P-channel MOS transistor P3 and an N-channel MOS transistor N3, and a series circuit of a P-channel MOS transistor P4 and an N-channel MOS transistor N4. The power potential VDD2C is supplied to respective sources of the transistors P1 to P4. A power potential (ground potential) VSS is supplied to respective sources of the transistors N1 to N4.

The fuse data D is commonly supplied to a gate electrode of the transistor P1 and a gate electrode of the transistor N2 via an N-channel MOS transistor N5. The fuse data D is commonly supplied to a gate electrode of the transistor P2 and a gate electrode of the transistor N1 via an N-channel MOS transistor N7. The fuse data DF is commonly supplied to a gate electrode of the transistor P3 and a gate electrode of the transistor N4 via an N-channel MOS transistor N8. The fuse data DF is commonly supplied to a gate electrode of the transistor N3 and a gate electrode of the transistor P4 via an N-channel MOS transistor N6. A fuse load signal FL0 output from the control circuit 24 is commonly supplied to respective gate electrodes of the transistors N5 and N6. A fuse load signal FL1 output from the control circuit 24 is commonly supplied to respective gate electrodes of the transistors N7 and N8.

The potential that appears at a common drain of the transistor P4 and the transistor N4 is output as the latch data Q and is fed back to the respective gate electrodes of the transistors P1 and N2. The potential that appears at a common drain of the transistor P1 and the transistor N1 is output as the latch data QF and is fed back to the respective gate electrodes of the transistors P3 and N4. The potential that appears at a common drain of the transistor P3 and the transistor N3 is output as the latch data Q1 and is fed back to the respective gate electrodes of the transistors P2 and N1. The potential that appears at a common drain of the transistor P2 and the transistor N2 is output as the latch data Q1F and is fed back to the respective gate electrodes of the transistors P4 and N3. With this configuration, when the fuse load signals FL0 and FL1 are activated, the logic level indicated by the fuse data D and DF is doubly latched in the DICE latch circuit 21.

The DICE latch circuit 21 may also include a CMOS logic circuit (not shown).

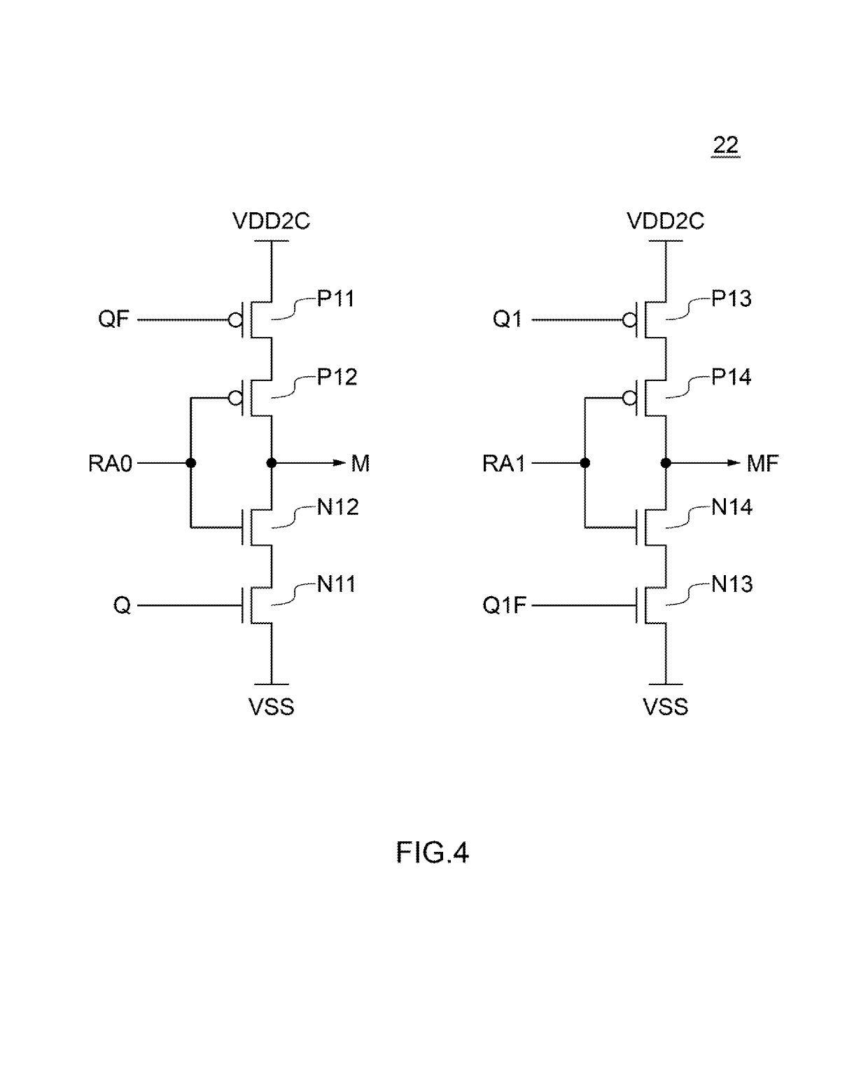

FIG. 4 is a circuit diagram of some of the circuits included in the selector circuit 22. As shown in FIG. 4, the selector circuit 22 includes a series circuit of P-channel MOS transistors P11 and P12 and N-channel MOS transistors N12 and N11 and a series circuit of P-channel MOS transistors P13 and P14 and N-channel MOS transistors N14 and N13. The power potential VDD2C is supplied to respective sources of the transistors P11 and P13. The power potential (ground potential) VSS is supplied to respective sources of the transistors N11 and N13.

The latch data Q, QF, Q1, and Q1F are supplied to gate electrodes of the transistors N11, P11, P13, and N13, respectively. A predetermined bit RA0 of the address RA is commonly supplied to respective gate electrodes of the transistors P12 and N12. The determination signal M is output from a common drain of the transistor P12 and the transistor N12. A predetermined bit RA1 of the address RA is commonly supplied to respective gate electrodes of the transistors P14 and N14. The determination signal MF is output from a common drain of the transistor P14 and the transistor N14. In this manner, a CMOS logic circuit is included in the selector circuit 22.

The determination signals M and MF generated as described above are supplied to the output circuit 23 shown in FIG. 2. Accordingly, when at least one of the determination signals M and MF is at a high level, the hit signal HIT is activated.

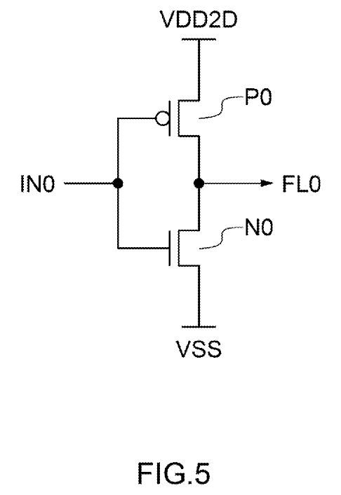

FIG. 5 is a circuit diagram of some of the circuits included in the control circuit 24. As shown in FIG. 5, a CMOS logic circuit in which the P-channel MOS transistor P0 and the N-channel MOS transistor N0 are connected to each other in series is also included in the control circuit 24. The power potential VDD2D is supplied to a source of the transistor P0. The power potential (ground potential) VSS is supplied to a source of the transistor N0. The CMOS logic circuit shown in FIG. 5 receives an input signal IN0 and outputs the fuse load signal FL0 to the DICE latch circuit 21.

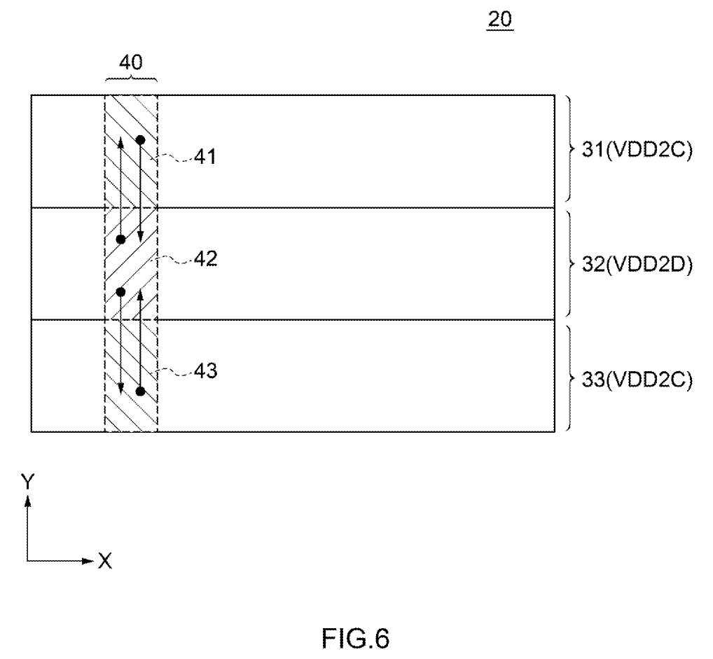

FIG. 6 is a schematic plan view for explaining a layout of the fuse latch circuit 20. As shown in FIG. 6, the fuse latch circuit 20 is arranged in circuit regions 31 to 33. Each of the circuit regions 31 to 33 extends in an X direction. The DICE latch circuit 21 and the selector circuit 22 each having the power potential VDD2C as the operation power source thereof are arranged in the circuit regions 31 and 33. Other circuits including the control circuit 24 each having the power potential VDD2D as the operation power source thereof are arranged in the circuit region 32. The circuit region 32 is sandwiched between the circuit region 31 and the circuit region 33 in a Y direction. Reference sign 40 shown in FIG. 6 represents a unit circuit repeatedly arranged in the X direction. In the unit circuit 40, both a circuit block 41 positioned in the circuit region 31 and a circuit block 43 positioned in the circuit region 33 are allocated to a circuit block 42 positioned in the circuit region 32. That is, each of signals output from the circuit blocks 41 and 43 (for example, the hit signal HIT) is supplied to the circuit block 42 via a wiring extending in the Y direction, and a signal output from the circuit block 42 (for example, the fuse load signal FL) is supplied to each of the circuit blocks 41 and 43 via a wiring extending in the Y direction. In this manner, since the circuit block 42 is allocated to two circuit blocks 41 and 43, the circuit block 42 is arranged to be sandwiched between the circuit blocks 41 and 43, so that the wiring density in the fuse latch circuit 20 can be decreased. Circuits arranged in the circuit block 41 and circuits arranged in the circuit block 43 may have the same circuit configuration as each other.

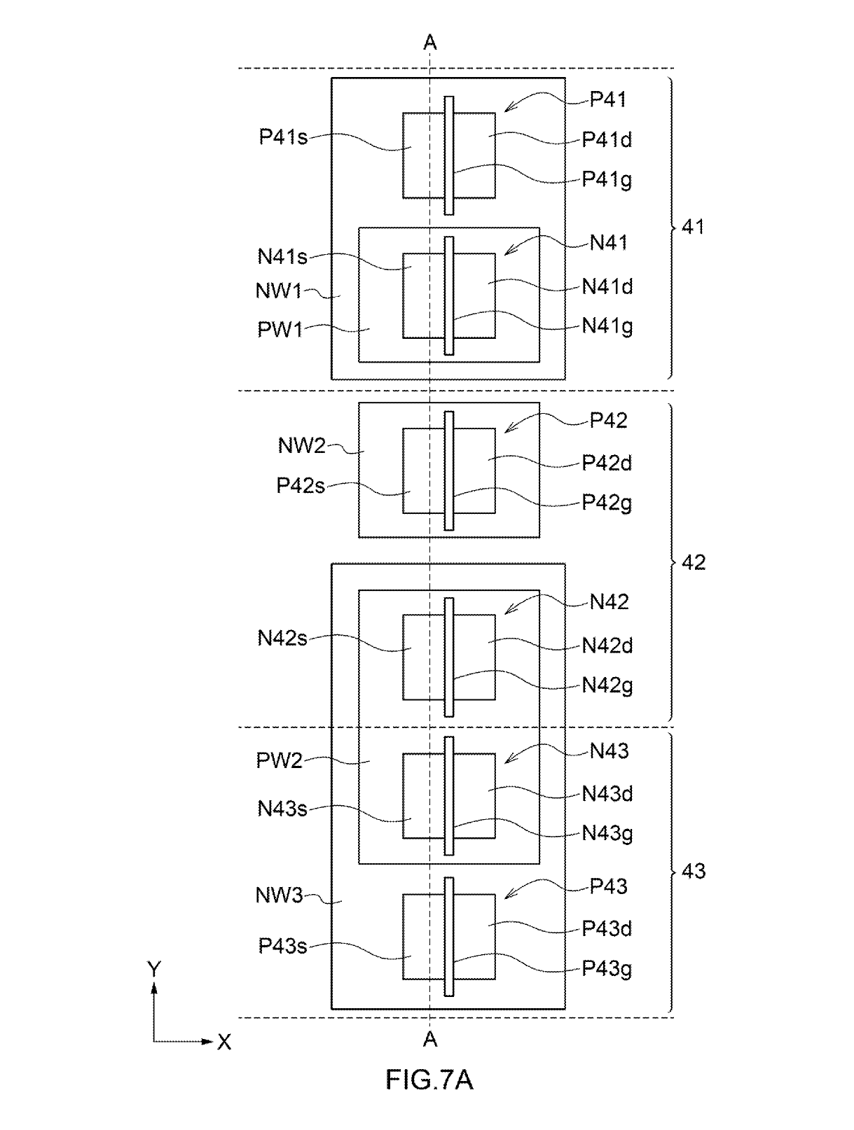

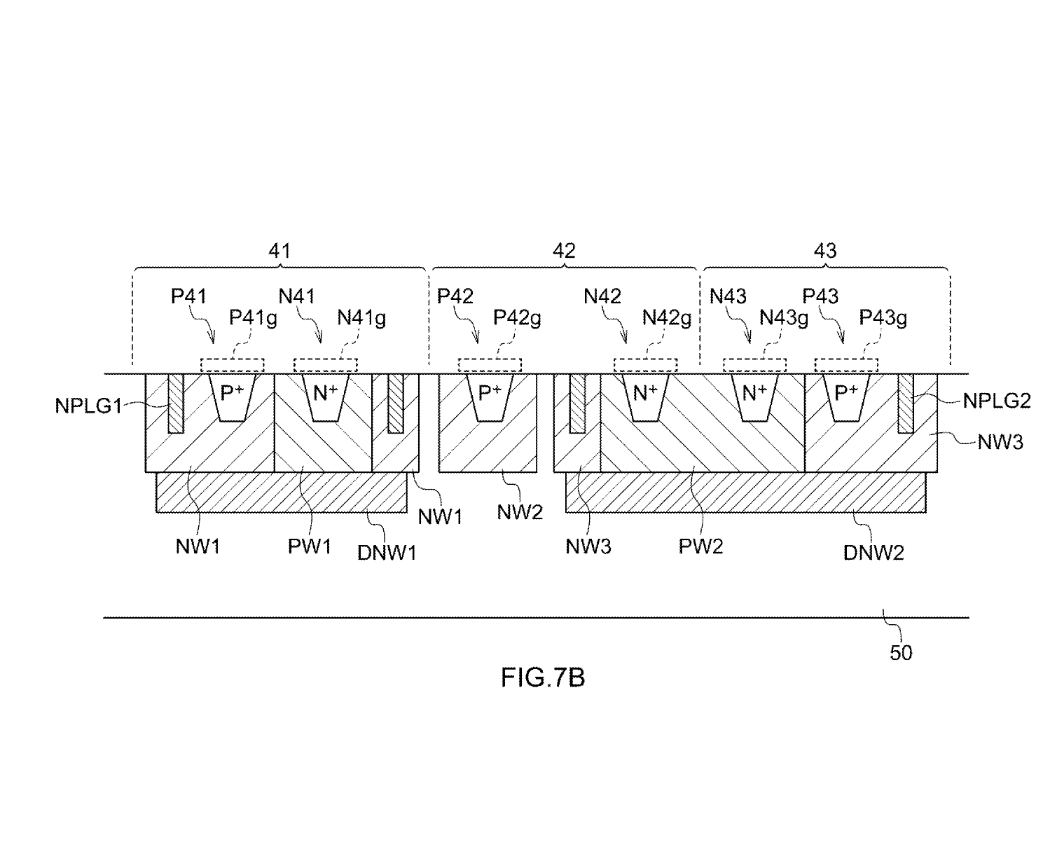

FIG. 7A is a schematic plan view for explaining a layout of transistors included in the circuit blocks 41 to 43. FIG. 7B is a schematic cross section along the line A-A shown in FIG. 7A.

A P-channel MOS transistor P41 and an N-channel MOS transistor N41 are included in the circuit block 41. The transistor P41 includes a source region P41s, a drain region P41d, and a gate electrode P41g. The transistor N41 includes a source region N41s, a drain region N41d, and a gate electrode N41g. The gate electrode P41g and the gate electrode N41g may be short-circuited. The drain region P41d and the drain region N41d may be short-circuited.

A P-channel MOS transistor P42 and an N-channel MOS transistor N42 are included in the circuit block 42. The transistor P42 includes a source region P42s, a drain region P42d, and a gate electrode P42g. The transistor N42 includes a source region N42s, a drain region N42d, and a gate electrode N42g. The gate electrode P42g and the gate electrode N42g may be short-circuited. The drain region P42d and the drain region N42d may be short-circuited.

A P-channel MOS transistor P43 and an N-channel MOS transistor N43 are included in the circuit block 43. The transistor 43 includes a source region P43s, a drain region P43d, and a gate electrode P43g. The transistor N43 includes a source region N43s, a drain region N43d, and a gate electrode N43g. The gate electrode P43g and the gate electrode N43g may be short-circuited. The drain region P43d and the drain region N43d may be short-circuited.

The transistors P41 and N41 are arranged in an Nwell region NW1 and a Pwell region PW1, respectively. In plan view, the Pwell region PW1 is surrounded by the Nwell region NW1. A well potential is supplied to the Nwell region NW1 via a ring-shaped plug NPLG1. A deep Nwell region DNW1 is provided at the respective bottoms of the Nwell region NW1 and the Pwell region PW1. The Pwell region PW1 is surrounded by the Nwell region NW1 and the deep Nwell region DNW1, so that the Pwell region PW1 is electrically isolated from a semiconductor substrate 50 to which the power potential (ground potential) VSS is supplied.

The transistor P42 is arranged in an Nwell region NW2. Any deep Nwell region is not provided at the bottom of the Nwell region NW2.

Both the transistors N42 and N43 are arranged in a Pwell region PW2. The transistor P43 is arranged in an Nwell region NW3. In plan view, the Pwell region PW2 is surrounded by the Nwell region NW3. A well potential is supplied to the Nwell region NW3 via a ring-shaped plug NPLG2. A deep Nwell region DNW2 is provided at the respective bottoms of the Nwell region NW3 and the Pwell region PW2. The Pwell region PW2 is surrounded by the Nwell region NW3 and the deep Nwell region DNW2, so that the Pwell region PW2 is electrically isolated from the semiconductor substrate 50 to which the power potential (ground potential) VSS is supplied.

In this manner, in the present embodiment, the transistor N42 belonging to the circuit block 42 having the power potential VDD2D as the operation power source thereof and the transistor N43 belonging to the circuit block 43 having the power potential VDD2C as the operation power source thereof are arranged in the same Pwell region PW2. The transistor P42 belonging to the circuit block 42 having the power potential VDD2D as the operation power source thereof is arranged independently in the Nwell region NW2 positioned between the Nwell region NW1 and the Nwell region NW3.

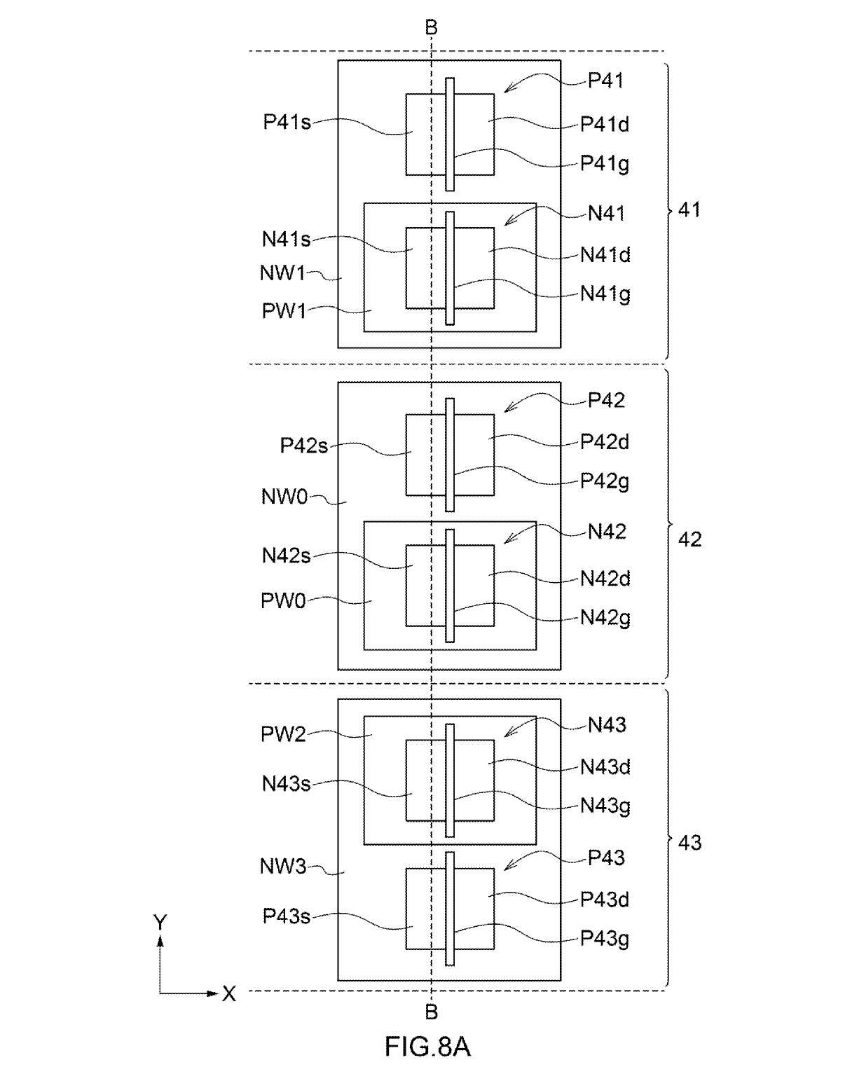

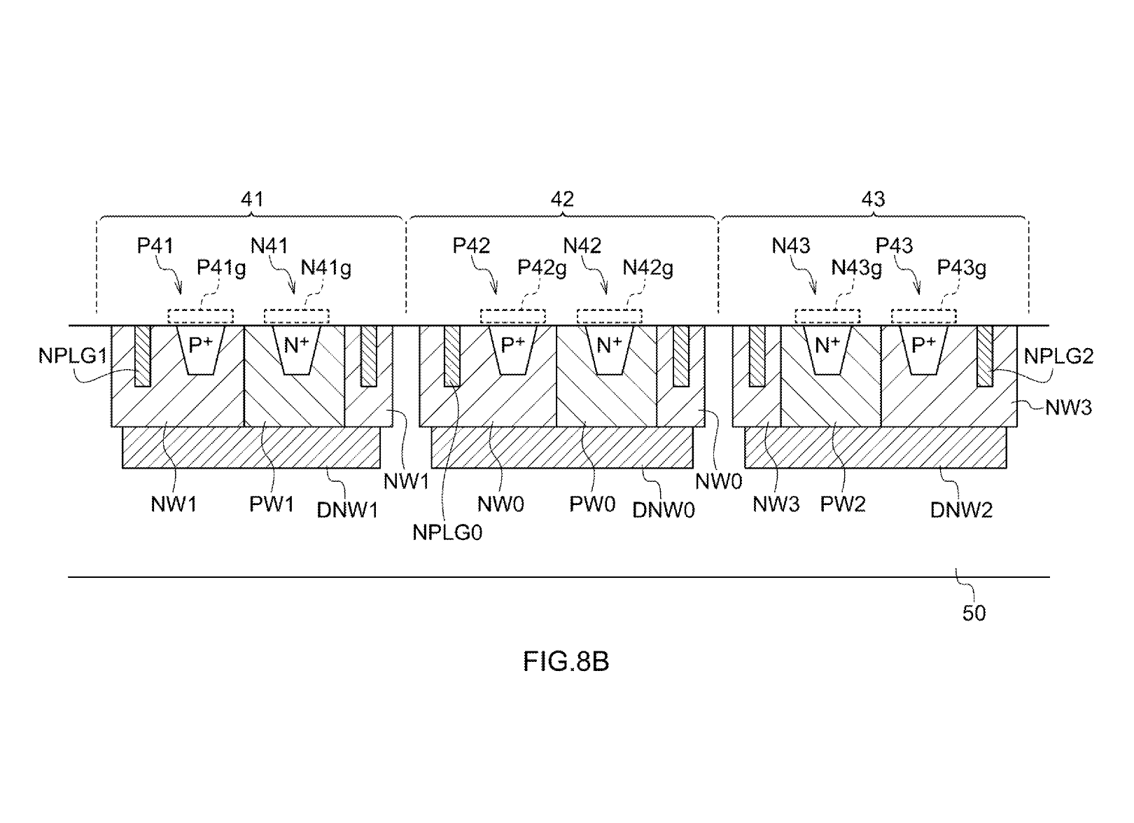

FIG. 8A is a schematic plan view for explaining a layout of transistors included in the circuit blocks 41 to 43 according to a comparative example. FIG. 8B is a schematic cross section along the line B-B shown in FIG. 8A. The layout according to the comparative example shown in FIGS. 8A and 8B is different from the layout shown in FIGS. 7A and 7B in a feature that the transistors P42 and N42 included in the circuit block 42 are arranged in an Nwell region NW0 and a Pwell region PW0, respectively. In plan view, the Pwell region PW0 is surrounded by the Nwell region NW0. A well potential is supplied to the Nwell region NW0 via a ring-shaped plug NPLG0. A deep Nwell region DNW0 is provided at the respective bottoms of the Nwell region NW0 and the Pwell region PW0. The Pwell region PW0 is surrounded by the Nwell region NW0 and the deep Nwell region DNW0, so that the Pwell region PW0 is electrically isolated from the semiconductor substrate 50 to which the power potential (ground potential) VSS is supplied.

As described above, in the layout according to the comparative example, the CMOS logic circuit included in the circuit block 41, the CMOS logic circuit included in the circuit block 42, and the CMOS logic circuit included in the circuit block 43 are completely separated from one another. On the other hand, in the layout shown in FIGS. 7A and 7B, the transistor N42 included in the circuit block 42 is arranged in the Pwell region PW2 in which the transistor N43 is arranged, so that the size of the Nwell region NW2 in which the transistor P42 included in the circuit block 42 is arranged can be downsized.

Furthermore, in the layout according to the comparative example, it is necessary to secure a sufficient space between the deep Nwell region DNW0 and the deep Nwell region DNW1 in the Y direction and a sufficient space between the deep Nwell region DNW0 and the deep Nwell region DNW2 in the Y direction, so that the size of each of the circuit blocks 41 to 43 becomes large. On the other hand, in the layout shown in FIGS. 7A and 7B, it is not necessary to provide any deep Nwell region at the bottom of the Nwell region NW2, so that it is possible to design the space between the Nwell region NW2 and the Nwell region NW1 and the space between Nwell region NW2 and the Nwell region NW3 to be narrow.

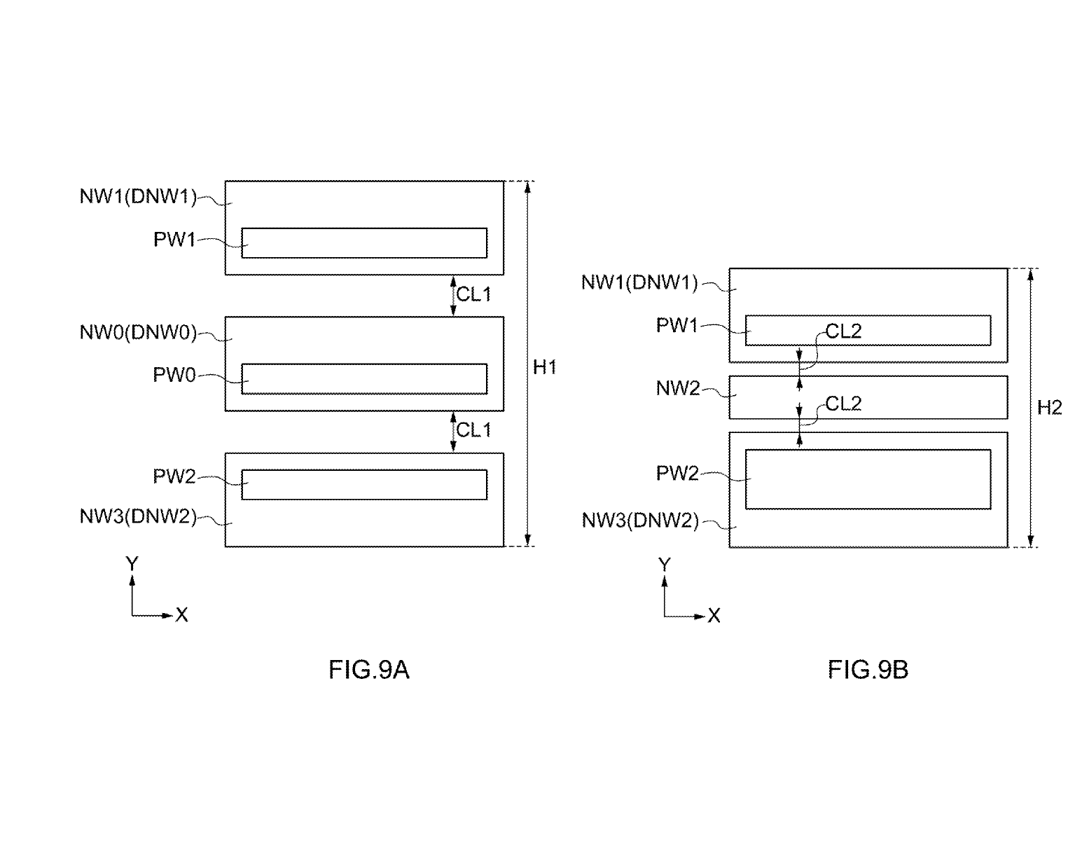

FIG. 9A is a schematic plan view of the layout according to the comparative example shown in FIGS. 8A and 8B. FIG. 9B is a schematic plan view of the layout shown in FIGS. 7A and 7B. As is clear from a comparison between the layout shown in FIG. 9A and the layout shown in FIG. 9B, as the size in the Y direction is H1 in the layout shown in FIG. 9A, the size in the Y direction is reduced to H2 in the layout shown in FIG. 9B. This difference is caused mainly because while three Pwell regions PW0 to PW2 are used in the layout shown in FIG. 9A, only two Pwell regions PW1 and PW2 are used in the layout shown in FIG. 9B. Furthermore, a large clearance CL1 needs to be provided between adjacent deep Nwell regions and it is necessary to provide this clearance CL1 in two positions in the layout shown in FIG. 9A. On the other hand, a clearance CL2 necessary to be provided between adjacent Nwell regions is smaller than the clearance CL1, so that in the layout shown in FIG. 9B, it is possible to reduce the size of the entire layout in the Y direction.

Although various embodiments have been disclosed in the context of certain preferred embodiments and examples, it will be understood by those skilled in the art that the scope of the present disclosure extends beyond the specifically disclosed embodiments to other alternative embodiments and/or uses of the embodiments and obvious modifications and equivalents thereof. In addition, other modifications which are within the scope of this disclosure will be readily apparent to those of skill in the art based on this disclosure. It is also contemplated that various combination or sub-combination of the specific features and aspects of the embodiments may be made and still fall within the scope of the disclosure. It should be understood that various features and aspects of the disclosed embodiments can be combined with or substituted for one another in order to form varying modes of the disclosed embodiments. Thus, it is intended that the scope of at least some of the present disclosure should not be limited by the particular disclosed embodiments described above.

1. A functional circuit comprising:
a first CMOS logic circuit supplied with a first voltage, the first CMOS logic circuit including a first PMOS transistor and a first NMOS transistor;
a second CMOS logic circuit supplied with a second voltage different from the first voltage, the second CMOS logic circuit including a second PMOS transistor and a second NMOS transistor; and
a third CMOS logic circuit supplied with the first voltage, the third CMOS logic circuit including a third PMOS transistor and a third NMOS transistor,
wherein the first, second and third PMOS transistors are independently provided in first, second and third nwells, respectively,
wherein the first NMOS transistor is provided in a first pwell, and
wherein the second and third NMOS transistors are provided in a second pwell.

2. The functional circuit of claim 1, wherein the first pwell is surrounded by the first nwell.

3. The functional circuit of claim 2, further comprising a first deep nwell located at a bottom of the first nwell and the first pwell such that the first pwell is electrically isolated from a semiconductor substrate.

4. The functional circuit of claim 3, wherein the second pwell is surrounded by the third nwell.

5. The functional circuit of claim 4, further comprising a second deep nwell located at a bottom of the third nwell and the second pwell such that the second pwell is electrically isolated from the semiconductor substrate.

6. The functional circuit of claim 5, wherein a bottom of the second nwell is free from a deep nwell.

7. The functional circuit of claim 6, wherein the second nwell is arranged between the first nwell and the third nwell.

8. The functional circuit of claim 1, wherein the second CMOS logic circuit is arranged between the first CMOS logic circuit and the third CMOS logic circuit.

9. The functional circuit of claim 8,
wherein each of the first and third CMOS logic circuits includes a latch circuit, and
wherein the second CMOS logic circuit includes a control circuit configured to control the latch circuit.

10. The functional circuit of claim 9,
wherein each of the first and third CMOS logic circuits further includes an output circuit, and
wherein the control circuit is configured to receive an output signal of the output circuit.

11. The functional circuit of claim 10, wherein the second voltage is lower than the first voltage.

12. The functional circuit of claim 1, wherein the first and third CMOS logic circuits have the same circuit configuration as each other.

13. A functional circuit comprising:
a first CMOS logic circuit including a first PMOS transistor and a first NMOS transistor; and
a second CMOS logic circuit including a second PMOS transistor and a second NMOS transistor,
wherein the first and second PMOS transistors are independently provided in first and second nwells, respectively,
wherein the first and second NMOS transistors are provided in a first pwell, and
wherein the first pwell is electrically isolated from a semiconductor substrate by the first nwell and a first deep nwell located at a bottom of the first nwell and the first pwell.

14. The functional circuit of claim 13,
wherein a source of the first PMOS transistor is supplied with a first power potential, and
wherein a source of the second PMOS transistor is supplied with a second power potential different from the first power potential.

15. The functional circuit of claim 14, wherein sources of the first and second NMOS transistors are supplied in common with a third power potential different from the first and second power potentials.

16. The functional circuit of claim 15, wherein a bottom of the second nwell is free from a deep nwell.

17. The functional circuit of claim 16, further comprising a third CMOS logic circuit including a third PMOS transistor and a third NMOS transistor,
wherein the second CMOS logic circuit is arranged between the first CMOS logic circuit and the third CMOS logic circuit,
wherein the third PMOS transistor is provided in a third nwell,
wherein the third NMOS transistor is provided in a second pwell,
wherein the second pwell is electrically isolated from the semiconductor substrate by the third nwell and a second deep nwell located at a bottom of the third nwell and the second pwell,
wherein a source of the third PMOS transistor is supplied with the first power potential, and
wherein a source of the third NMOS transistor is supplied with the third power potential.

18. The functional circuit of claim 17, wherein the first and third CMOS logic circuits have the same circuit configuration as each other.

19. An apparatus comprising:
a functional circuit including a first PMOS transistor and a first NMOS transistor; and
a control circuit configured to control the functional circuit, and including a second PMOS transistor and a second NMOS transistor,
wherein the first PMOS transistor has a source region supplied with a first power potential, a drain region, and a gate electrode,
wherein the first NMOS transistor has a source region supplied with a second power potential lower than the first power potential, a drain region electrically connected to the drain region of the first PMOS transistor, and a gate electrode electrically connected to the gate electrode of the first PMOS transistor,
wherein the second PMOS transistor has a source region supplied with a third power potential lower than the first power potential and higher than the second power potential, a drain region, and a gate electrode,
wherein the second NMOS transistor has a source region supplied with the second power potential, a drain region electrically connected to the drain region of the second PMOS transistor, and a gate electrode electrically connected to the gate electrode of the second PMOS transistor, and
wherein the source and drain regions of the first NMOS transistor and the source and drain regions of the second NMOS transistor are provided in a first pwell in common.

20. The apparatus of claim 19,
wherein the source and drain regions of the first PMOS transistor are provided in a first nwell,
wherein the source and drain regions of the second PMOS transistor are provided in a second nwell, and
wherein the first pwell is surrounded by the first nwell.
